(19) United States
(12) Patent Application Publication
(10) Pub. No.: US 2013/0114767 A1
(43) Pub. Date: May 9, 2013

(54) APPARATUS AND METHOD FOR ENHANCING CHANNEL ESTIMATION ACCURACY IN COMMUNICATION SYSTEM

(71) Applicants: You Seok LEE, Daejeon (KR); Jae Hyun SEO, Daejeon (KR); Heung Mook KIM, Daejeon (KR); Nam Ho HUR, Daejeon (KR)

(72) Inventors: You Seok LEE, Daejeon (KR); Jae Hyun SEO, Daejeon (KR); Heung Mook KIM, Daejeon (KR); Nam Ho HUR, Daejeon (KR)

(73) Assignee: Electronics and Telecommunications Research Institute, Daejeon (KR)

(21) Appl. No.: 13/620,787

(22) Filed: Sep. 15, 2012

(30) Foreign Application Priority Data
Nov. 7, 2011 (KR) 10-2011-0115070

(51) Int. Cl. H03D 1/04

(52) U.S. Cl. 375/346

(57) ABSTRACT

An apparatus and method for calculating a correlation value using a first channel impulse response estimated from a received signal, determining a weight value based on the correlation value, applying the weight value to the first channel impulse response, and estimating a second channel impulse response is provided.

### CROSS-REFERENCE TO RELATED APPLICATION

This application claims the priority benefit of Korean Patent Application No. 10-2011-0115070, filed on Nov. 7, 2011, in the Korean Intellectual Property Office, the disclosure of which is incorporated herein by reference.

### BACKGROUND

1. Field of the Invention

The present invention relates to an apparatus and method for enhancing accuracy of an estimated channel coefficient in a communication system.

2. Description of the Related Art

In general, recovering a transmission signal in a communication system is achieved by compensating for a channel distortion during transmission, by using a method of estimating a channel, and cancelling interference through an interference estimation.

A conventional channel estimation algorithm improves a channel estimation performance with an emphasis on a method of selecting an effective channel impulse response (CIR) component from an estimated CIR to attenuate an effect of noise from an initial channel coefficients estimated using a pilot signal.

In this instance, all CIR components to be selected based on a channel environment may not be the effective CIR, and thus the effect of noise may not be fully removed.

A method of verifying a high quality channel estimate of a communication system may include a method of estimating channel coefficients by selecting a thresholding parameter.

A general channel estimating apparatus verifies a first CIR estimate including multiple channel tabs by filtering an initial channel impulse response estimate (CIRE) that is obtained from a received pilot.

A channel estimating apparatus may select a thresholding parameter based on a channel profile, a motion Signal to Noise Ratio (SNR), a number of channel tabs, and the like, and verify a second CIRE by zeroing out the channel tabs having a lower energy value than a threshold value based on the selected thresholding parameter value.

The apparatus for estimating a channel configured as above may be unable to remove a portion of noise or may be significantly influenced by a channel tab of a small size. Accordingly, there is a need for a channel estimating apparatus that may enhance accuracy of channel estimation by decreasing an effect of a channel tab of a small size and having low noise.

### SUMMARY

According to an aspect of the present invention, there is provided an apparatus for estimating a channel, the apparatus including a first channel response estimating unit to estimate a first channel impulse response from a received signal, a weight calculating unit to determine a weight value applied to each channel coefficient using the first channel impulse response, and a second channel response estimating unit to estimate a second channel impulse response by applying the weight value to the first channel impulse response.

The weight calculating unit may include a correlation calculating unit to calculate a correlation value using the first channel impulse response.

The correlation calculating unit may calculate the correlation value using an auto-correlation value of the first channel impulse response or using a correlation value of a reference signal.

The weight calculating unit may further include a weight determining unit to determine the weight value applied to each channel coefficient, by using the result of the calculated correlation value.

According to another aspect of the present invention, there is provided an apparatus for estimating a channel including a first channel response estimating unit to estimate a first channel frequency response from a received signal, a first converting unit to convert the first channel frequency response to a first channel impulse response, a weight calculating unit to determine a weight value applied to each channel coefficient using the first channel impulse response, a second channel response estimating unit to estimate a second channel impulse response by applying the determined weight value to the first channel impulse response, and a second converting unit to convert the second channel impulse response to a second channel frequency response.

The weight calculating unit may include a correlating unit to calculate a correlation value, by using the first channel impulse response.

The weight calculating unit may further include a weight determining unit to determine the weight value applied to each channel coefficient, by using the result of the calculated correlation value.

According to still another aspect of the present invention, there is provided a method of estimating a channel, the method including estimating a first channel impulse response from a received signal using the first channel impulse response, calculating a correlation value using the first channel impulse response, determining a weight value based on the calculated correlation value, and estimating a second channel impulse response by applying the determined weight value to the first channel impulse response.

The determining may include determining the weight value using at least one of the correlation values, a distribution of the first channel impulse response, an average energy value of the correlation value, and an average energy value of the first channel impulse response.

The estimating of the second channel impulse response may include estimating the second channel impulse response by multiplying or adding the determined weight value and the first channel impulse response.

The estimating of the second channel impulse response may further include estimating the second impulse response by removing or maintaining the first channel impulse response, when the weight value is zero.

According to yet another aspect of the present invention, there is provided a method of estimating a channel, the method including estimating a first channel frequency response from a received signal, converting the first channel frequency response to a first channel impulse response in a form of a time domain signal, calculating a correlation value using the first channel impulse response, determining a weight value based on the correlation value, estimating a second impulse response by applying the determined weight value to the first channel impulse response, and converting the second channel impulse response to a second channel frequency response in the form of a frequency domain signal.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating an apparatus for estimating a channel according to an embodiment of the present invention;

FIG. 2 is a block diagram illustrating a detailed configuration of an apparatus for estimating a channel according to an embodiment of the present invention;

FIG. 3 is a block diagram illustrating a configuration of an apparatus for estimating a channel according to another embodiment of the present invention;

FIG. 4 is a block diagram illustrating a detailed configuration of an apparatus for estimating a channel according to another embodiment of the present invention;

FIG. 5 is a flowchart illustrating a method of estimating a channel according to an embodiment of the present invention;

FIG. 6 is a flowchart illustrating a method of estimating a channel according to another embodiment of the present invention; and

FIG. 7 illustrates a process of calculating a channel impulse response in a method of estimating a channel according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

When it is determined that a detailed description related to a related known function or configuration which may make the purpose of the present invention unnecessarily ambiguous in the description of the present invention, such detailed description will be omitted. Also, terminologies used herein are defined to appropriately describe the exemplary embodiments of the present invention and thus may be changed depending on a user, the intent of an operator, or a custom. Accordingly, the terminologies must be defined based on the following overall description of this specification.

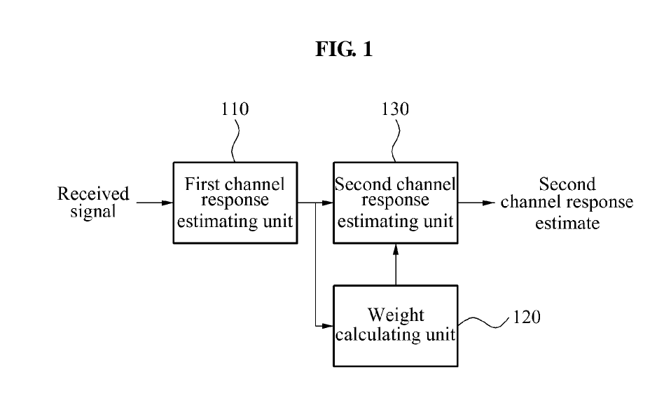

FIG. 1 is a block diagram illustrating an apparatus for estimating a channel according to an embodiment of the present invention.

Referring to FIG. 1, an apparatus for estimating a channel includes a first channel response estimating unit 110 to estimate a first channel impulse response from a received signal, a weight calculating unit 120 to determine a weight value applied to each channel coefficient using the first channel impulse response, and a second channel response estimating unit 130 to estimate a second channel impulse response by applying the weight value to the first channel impulse response.

According to an embodiment of the present invention, the apparatus for estimating the channel may estimate an initial channel impulse response including multiple channel tabs of a communication system, obtain a weight value to be applied to each channel coefficient from a first channel impulse response initially estimated, apply the weight value to the first channel impulse response to adjust each channel impulse response value and thus, obtain a second channel impulse response.

Hereinafter, a configuration of a weight calculating unit of an apparatus for estimating a channel according to an embodiment of the present invention will be described in detail.

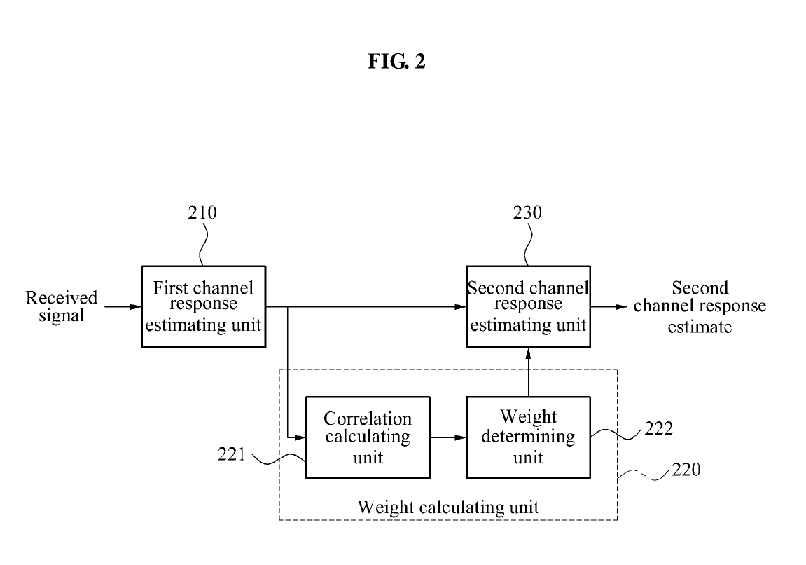

FIG. 2 is a block diagram illustrating a detailed configuration of an apparatus for estimating a channel according to an embodiment of the present invention.

Referring to FIG. 2, a weight calculating unit 220 includes a correlation calculating unit 221 to calculate a correlation value using a first channel impulse response estimated from a first channel response estimating unit 210.

According to an embodiment of the present invention, the correlation calculating unit 221 may calculate a correlation value using an auto-correlation value of the first channel impulse response, or calculate the correlation value using a correlation value of a reference signal.

The weight calculating unit 220 further includes a weight determining unit 222 to determine the weight value using the result of the calculated correlation value. The weight calculating unit 220 may obtain a second channel impulse response by providing the determined weight value to a second channel response estimating unit 230.

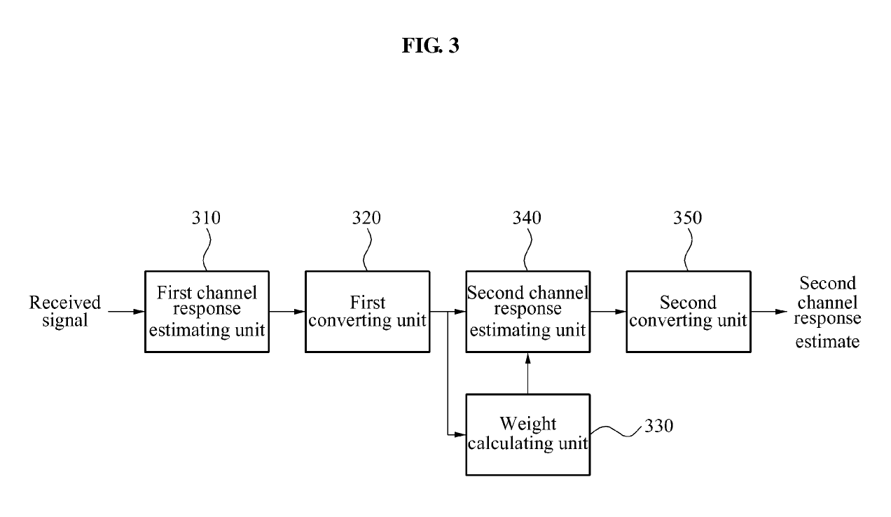

Hereinafter, an apparatus for estimating a channel in a case in which an estimated channel response is a frequency response according to another embodiment of the present invention will be described with reference to FIG. 3.

FIG. 3 is a block diagram illustrating a configuration of an apparatus for estimating a channel according to another embodiment of the present invention.

Referring to FIG. 3, an apparatus for estimating a channel according to another embodiment of the present invention includes a first channel response estimating unit 310 to estimate a first channel frequency response from a received signal, a first converting unit 320 to convert the first channel frequency response to a first channel impulse response, a weight calculating unit 330 to determine a weight value applied to each channel coefficient using the first channel impulse response, a second channel response estimating unit 340 to estimate a second channel impulse response by applying the weight value to the first channel impulse response, and a second converting unit 350 to convert the second channel impulse response to a second channel frequency response.

According to another embodiment of the present invention, an apparatus for estimating a channel may obtain a weight value using a channel impulse response converted to a time domain coefficient when an estimated channel response is a frequency response, and obtain a channel response of a second frequency domain by converting to a frequency domain signal a second channel impulse response in which each channel tab coefficient is adjusted by the weight value.

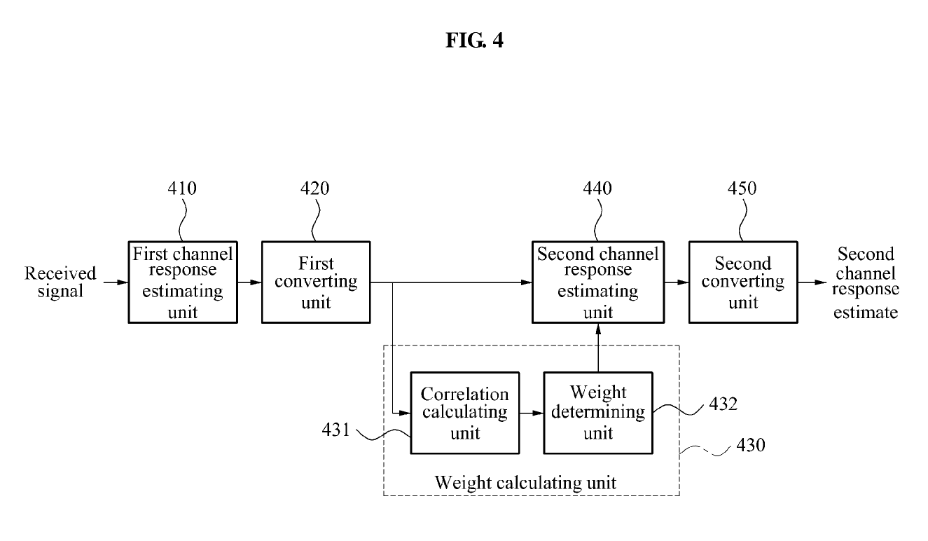

FIG. 4 is a block diagram illustrating a detailed configuration of an apparatus for estimating a channel according to another embodiment of the present invention.

Referring to FIG. 4, a weight calculating unit 430 includes a correlation calculating unit 431 to calculate a correlation value using the first channel impulse response estimated and converted via a first channel response estimating unit 410 and a first converting unit 420.

According to another embodiment of the present invention, the correlation calculating unit 431 may calculate a correlation value using an auto-correlation value of the first channel impulse response, or calculate the correlation value using a correlation value of a reference signal.

The weight calculating unit 430 further includes a weight determining unit 432 to determine the weight value using the result of the calculated correlation value, and obtains the second channel impulse response by providing the determined weight value to a second channel response estimating unit 440.

According to another embodiment of the present invention, a second converting unit 450 may convert the second channel impulse response to a second channel frequency response.

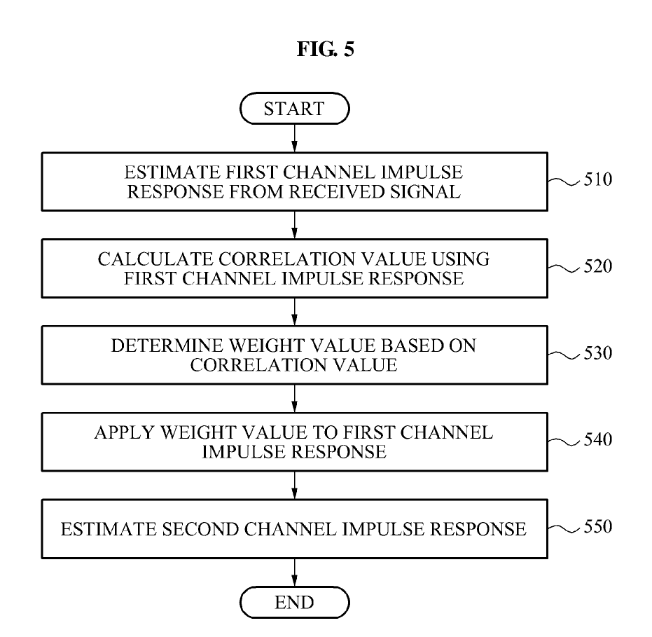

Hereinafter, a method of estimating a channel according to an embodiment of the present invention will be described with reference to FIG. 5.

FIG. 5 is a flowchart illustrating a method of estimating a channel according to an embodiment of the present invention.

Referring to FIG. 5, in operation 510, an apparatus for estimating a channel according to an embodiment of the present invention estimates a first channel impulse response from a received signal.

In operation 520, the apparatus for estimating the channel calculates a correlation value using the first channel impulse response.

In operation 530, the apparatus for estimating the channel determines a weight value based on the correlation value.

In operation 530, the apparatus for estimating the channel may determine the weight value using varied information such as the correlation value, a distribution of the first channel impulse response, an average energy value of the correlation value, or an average energy value of the first channel impulse response.

The apparatus for estimating the channel applies the weight value to the first channel impulse response, in operation 540, and estimates a second channel impulse response, in operation 550.

In operation 550, the apparatus for estimating the channel according to an embodiment of the present invention may estimate the second channel impulse response by multiplying or adding the first channel impulse response and the weight value.

When the weight value is zero in operation 550, the apparatus for estimating the channel according to an embodiment of the present invention may estimate the second channel impulse response by removing or maintaining the first channel impulse response.

For example, when the weight value is zero, the apparatus for estimating the channel may remove the first channel impulse response with respect to a corresponding tab when the first channel impulse response is multiplied by zero, and may not change the first channel impulse response with respect to a corresponding tab when zero is added to the first channel impulse response.

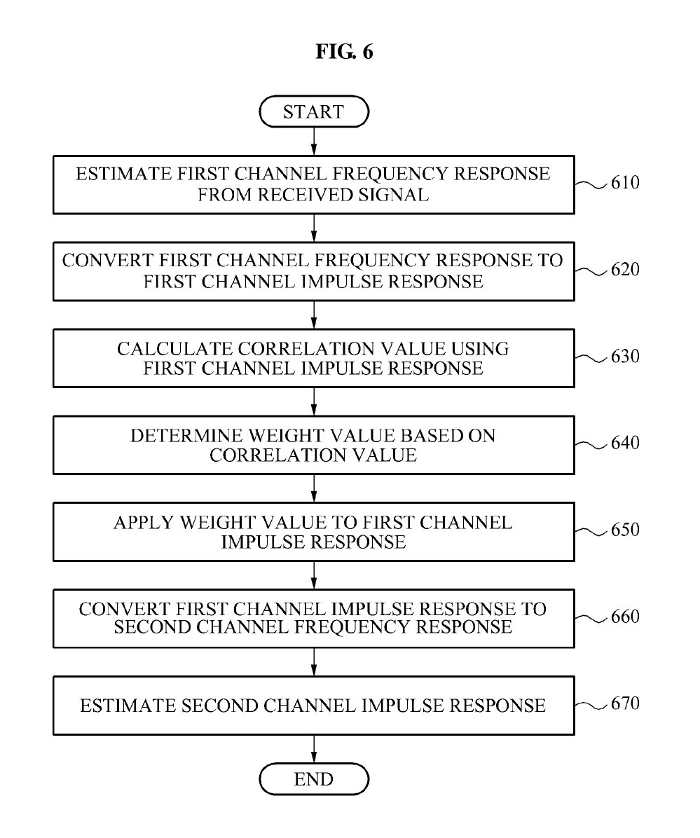

Hereinafter, a method of estimating a channel according to another embodiment of the present invention will be described with reference to FIG. 6.

FIG. 6 is a flowchart illustrating a method of estimating a channel according to another embodiment of the present invention.

Referring to FIG. 6, in operation 610, an apparatus for estimating the channel according to another embodiment of the present invention estimates a first channel frequency response from a received signal.

In operation 620, the apparatus for estimating the channel converts the first channel frequency response to a first channel impulse response in a form of a time domain signal.

In operation 630, the apparatus for estimating the channel calculates a correlation value using the first channel impulse response.

In operation 640, the apparatus for estimating the channel determines a weight value based on the weight value.

In operation 640 of determining the weight value, the apparatus for estimating the channel may determine the weight value using varied information such as the correlation value, a distribution of the first channel impulse response, an average energy value of the correlation value, or an average energy value of the first channel impulse response.

The apparatus for estimating the channel applies the weight value to the first channel impulse response, in operation 650, and estimates a second channel impulse response in operation 660.

In operation 670, the apparatus for estimating the channel converts the second channel impulse response to a second channel frequency response in a form of a frequency to domain signal.

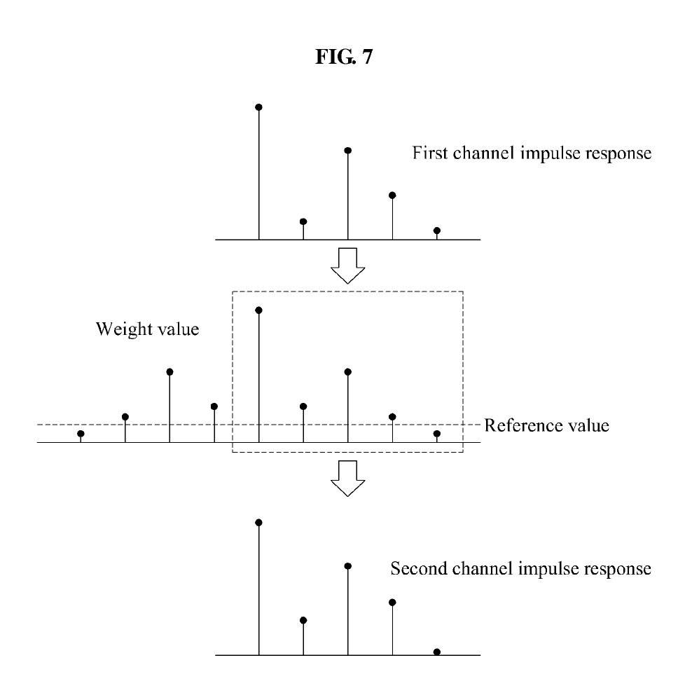

FIG. 7 illustrates a process of calculating a channel impulse response in a method of estimating a channel according to an embodiment of the present invention.

As shown in FIG. 7, a number of correlation values used as a weight value may be plural. When the plurality of correlation values is higher than a reference value, the weight value may be determined to be “1” and when the plurality of correlation values is lower than the reference value the weight value may be determined to be zero, or may have different values respectively.

According to an embodiment of the present invention, the reference value may be estimated or determined from a distribution of the correlation value and the like.

According to an embodiment of the present invention, an apparatus and method for enhancing channel estimation accuracy may be provided, and an effect of a channel tab having a small size and low noise be reduced by applying a weight to a channel coefficient estimated from an apparatus for estimating a channel of a communication system.

The above-described exemplary embodiments of the present invention may be recorded in computer-readable media including program instructions to implement various operations embodied by a computer. The media may also include, alone or in combination with the program instructions, data files, data structures, and the like. Examples of computer-readable media include magnetic media such as hard disks, floppy disks, and magnetic tape; optical media such as CD ROM discs and DVDs; magneto-optical media such as floptical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention, or vice versa.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. An apparatus for estimating a channel, the apparatus comprising:
a first channel response estimating unit to estimate a first channel impulse response from a received signal;
a weight calculating unit to determine a weight value applied to each channel coefficient using the first channel impulse response; and
a second channel response estimating unit to estimate a second channel impulse response by applying the weight value to the first channel impulse response.

2. The apparatus of claim 1, wherein the weight calculating unit comprises a correlation calculating unit to calculate a correlation value using the first channel impulse response.

3. The apparatus of claim 2, wherein the correlation calculating unit calculates the correlation value using an auto-correlation value of the first channel impulse response or using a correlation value of a reference signal.

4. The apparatus of claim 2, wherein the weight calculating unit further comprises:
a weight determining unit to determine the weight value applied to each channel coefficient, by using the result of the calculated correlation value.

5. An apparatus for estimating a channel, the apparatus comprising:
a first channel response estimating unit to estimate a first channel frequency response from a received signal;
a first converting unit to convert the first channel frequency response to a first channel impulse response;
a weight calculating unit to determine a weight value applied to each channel coefficient using the first channel impulse response;
a second channel response estimating unit to estimate a second channel impulse response by applying the determined weight value to the first channel impulse response; and
a second converting unit to convert the second channel impulse response to a second channel frequency response.

6. The apparatus of claim 5, wherein the weight calculating unit comprises a correlating unit to calculate a correlation value, by using the first channel impulse response.

7. The apparatus of claim 6, wherein the weight calculating unit further comprises a weight determining unit to determine the weight value applied to each channel coefficient, by using the result of the calculated correlation value.

8. A method of estimating a channel, the method comprising:
estimating a first channel impulse response from a received signal using the first channel impulse response;
calculating a correlation value using the first channel impulse response;
determining a weight value based on the calculated correlation value; and
estimating a second channel impulse response by applying the determined weight value to the first channel impulse response.

9. The method of claim 8, wherein the determining comprises determining the weight value using at least one of the correlation value, a distribution of the first channel impulse response, an average energy value of the correlation value, and an average energy value of the first channel impulse response.

10. The method of claim 8, wherein the estimating of the second channel impulse response comprises estimating the second channel impulse response by multiplying or adding the determined weight value and the first channel impulse response.

11. The method of claim 10, wherein the estimating of the second channel impulse response further comprises estimating the second impulse response by removing or maintaining the first channel impulse response, when the weight value is zero.

12. A method of estimating a channel, the method comprising:
estimating a first channel frequency response from a received signal;
converting the first channel frequency response to a first channel impulse response in a form of a time domain signal;
calculating a correlation value using the first channel impulse response;
determining a weight value based on the correlation value;
estimating a second impulse response by applying the determined weight value to the first channel impulse response; and
converting the second channel impulse response to a second channel frequency response in a form of a frequency domain signal.

13. The method of claim 12, wherein the determining comprises determining the weight value using at least one of the correlation value, a distribution of the first channel impulse response, an average energy value of the correlation value, and an average energy value of the first channel impulse response.
